(19) United States
(12) Patent Application Publication
(10) Pub. No.: US 2026/0262265 A1
(43) Pub. Date: Sep. 3, 2026

(54) SEMICONDUCTOR DEVICE MANUFACTURING METHOD AND SEMICONDUCTOR DEVICE

(71) Applicant: Minebea Power Semiconductor Device Inc., Ibaraki (JP)

(72) Inventors: Hidekatsu ONOSE, Tokyo (JP); Tomoyasu FURUKAWA, Tokyo (JP)

(21) Appl. No.: 18/871,521

(22) PCT Filed: Apr. 4, 2023
(86) PCT No.: PCT/JP2023/013895

§ 371 Date: Dec. 4, 2024

(30) Foreign Application Priority Data
Jun. 17, 2022 (JP) 2022-097892

(51) Int. Cl. H10D 62/10; H10P 30/20; H10P 30/22

(52) U.S. Cl. CPC H10D 62/107; H10P 30/21; H10P 30/22

(57) ABSTRACT

The semiconductor device manufacturing method is for a semiconductor device that has, in the periphery of the active region, a termination region in which a first semiconductor region of a first electroconductive type has formed on the surface thereof a second semiconductor region that is a plurality of well regions of a second electroconductive type. Said method is characterized by forming the second semiconductor region by injecting impurities of the second electroconductive type using, as a mask for forming the second semiconductor region, a mask with which an interval S(x) is substantially equal to the value defined by S(x)=Smax−(Smax−Smin)·(x/XN)^{1/2}, where x is the distance from the reference window at the outermost periphery and the interval S(x) is the interval between the injection window in a position at the distance x and one injection window on the active region side thereof.

### TECHNICAL FIELD

The present invention relates to a method for manufacturing a semiconductor device and a semiconductor device.

### BACKGROUND ART

In recent years, price competition has intensified in the field of power semiconductor devices, and there is a demand for cost reduction. In order to reduce costs, it is necessary to increase the diameter of a wafer, to lower a process temperature, and to reduce the size of a chip, which requires making a junction in a termination region shallower, reducing the width of the termination region, and suppressing electric field concentration in the termination region.

Patent Literature 1 discloses, as a structure of a termination region, for example, a termination structure (32) provided on an outer peripheral portion of a semiconductor element. The termination region (32) includes an N-type drift region (1) formed in a semiconductor substrate (30) and a P-type impurity region (2) formed on an upper surface portion in the N-type drift region (1). When viewed macroscopically, a P-type impurity concentration of the P-type impurity region (2) decreases from an inner peripheral portion to an outer peripheral portion of the termination structure (32), and when viewed microscopically, the P-type impurity region (2) is constituted by a plurality of P-type high concentration regions (2b) and low concentration regions (2a) surrounding them, with some portions at which the low concentration regions (2a) are separated from each other (Abstract, FIG. 2).

In addition, Patent Literature 1 discloses that an aperture ratio of an injection mask (20) used in ion injection to form such a P-type impurity region (2) is reduced toward the outside of the termination structure (32) (paragraph 0042), and discloses that while examples of a function for reducing the aperture ratio include a linear function and the like, a function with a high rate of reduction such as an exponential function is desirable, and that, for example, by using an exponential function that is convex downward or a function that decreases according to a polynomial when viewed macroscopically, local concentration of the electric field can be alleviated (paragraph 0043).

### CITATION LIST

### Patent Literature

Patent Literature 1: WO 2014/054319

### SUMMARY OF INVENTION

### Technical Problem

However, Patent Literature 1 discloses, as the function for reducing the aperture ratio of the injection mask (20), the linear function, the exponential function (ax) that is convex downward, or the function that decreases according to the polynomial. However, as a result of simulations performed by the inventors of the present application, it has been found that the shape of the mask for reducing the width of the termination region and suppressing the electric field concentration in the termination region is desirably a different shape other than that specified by the functions disclosed in Patent Literature 1.

An object of the present invention is to provide a method for manufacturing a semiconductor device and a semiconductor device by which it is possible to realize reduction of the width of a termination region and suppression of electric field concentration in the termination region.

### Solution to Problem

In order to achieve the above-described object, a method for manufacturing a semiconductor device of the present invention is, for example, a method for manufacturing a semiconductor device that includes, in a periphery of an active region, a termination region in which second semiconductor regions, which are a plurality of well regions having a second conductivity type, are formed in a front surface of a first semiconductor region having a first conductivity type, wherein the second semiconductor regions are formed by injecting impurities of the second conductivity type using, as a mask for forming the second semiconductor regions, a mask in which a spacing S(x) between an injection window at a position of a distance x and the next injection window on a side of the active region is substantially equal to a value specified by S(x)=Smax−(Smax−Smin)·(x/XN)^{1/2},
where, out of the second semiconductor regions at which a depletion layer spreading into the first semiconductor region is continuous with the active region in a thermal equilibrium state, the injection window corresponding to the second semiconductor region formed at a position farthest from the active region is defined as a reference window, a position of the reference window on a side of the active region is defined as X0, a distance between a position of the injection window adjacent to the active region on a side of the active region and X0 is defined as XN, a spacing between the reference window and the next injection window on a side of the active region is defined as Smax, a spacing between an end portion of the active region and the injection window adjacent to the active region is defined as Smin, and a distance from X0 is defined as x.

In addition, a semiconductor device of the present invention is, for example, a semiconductor device including an active region and a termination region formed in a periphery of the active region, wherein the second semiconductor region formed using the method described above is included in the termination region.

### Advantageous Effects of Invention

According to the present invention, it is possible to realize a method for manufacturing a semiconductor device and a semiconductor device by which it is possible to realize reduction of the width of a termination region and suppression of electric field concentration in the termination region.

### BRIEF DESCRIPTION OF DRAWINGS

FIG. 1 is a cross-sectional view of a semiconductor device of Example 1.

FIG. 2 is a plan view illustrating a shape of a mask of Example 1.

FIG. 3 is a diagram illustrating a spacing between an injection window and the next injection window on a side of an active region in the mask of Example 1, and a width of the injection window.

FIG. 4 is a diagram illustrating a dose profile of Example 1.

FIG. 5 is a diagram illustrating a dose profile of Example 2.

FIG. 6 is a diagram illustrating a spacing between an injection window and the next injection window on a side of an active region in a mask of Example 3, and a width of the injection window.

FIG. 7 is a diagram illustrating a spacing between an injection window and the next injection window on a side of an active region in a mask of Example 4, and a width of the injection window.

FIG. 8 is a diagram illustrating the effect of the present invention.

FIG. 9 is a diagram illustrating the effect of the present invention.

### DESCRIPTION OF EMBODIMENTS

Hereinafter, examples of the present invention will be described with reference to the drawings. In each drawing and each example, the same or similar constituent elements are designated by the same reference signs, and the overlapping description will be omitted.

### Example 1

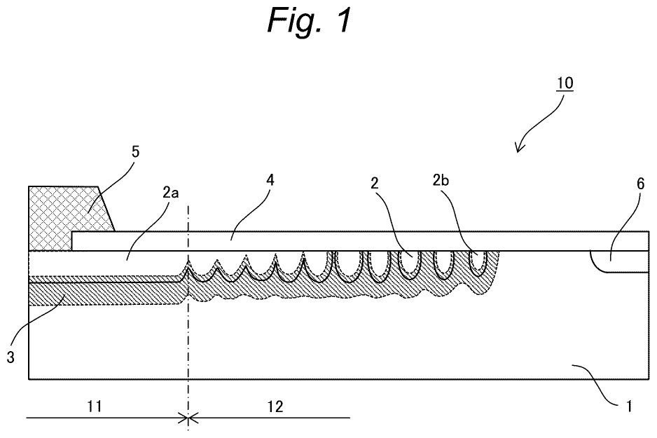

FIG. 1 is a cross-sectional view of a semiconductor device of Example 1.

A semiconductor device 10 of Example 1 includes, in a periphery of an active region 11, a termination region 12 in which second semiconductor regions 2, which are a plurality of well regions having a second conductivity type (for example, a p-type), are formed in a front surface of a first semiconductor region 1 having a first conductivity type (for example, an n-type). Here, description is made with the first conductivity type being the n-type and with the second conductivity type being the p-type, but the first conductivity type may be the p-type and the second conductivity type may be the n-type.

In the active region 11, a semiconductor element such as an insulated gate bipolar transistor (IGBT), a metal oxide semiconductor field effect transistor (MOSFET), a diode, or the like is formed, but is not shown in the drawing. A semiconductor substrate on which the semiconductor device 10 is formed may be made of Si, SiC, or the like but the present invention is not limited to this.

The first semiconductor region 1 and the second semiconductor region 2 are also formed in the active region 11, and the second semiconductor region 2 in the active region 11 will be referred to herein as a second semiconductor region 2a.

In addition, the semiconductor device 10 includes an oxide film 4 that is formed to cover the first semiconductor region 1 or the second semiconductor region 2, an electrode 5 that is formed in the active region 11, and a channel stopper 6 that is formed in the termination region and has a high concentration of a first conductivity type. The electrode 5 is, for example, a gate electrode or an emitter electrode in the case of an IGBT, a gate electrode or a source electrode in the case of a MOSFET, or an anode electrode in the case of a diode. In FIG. 1, only a front surface side of the semiconductor device 10 is shown, and a back surface side is not shown. On the back surface side of the semiconductor device 10, an electrode (not shown), for example, a collector electrode in the case of the IGBT, a drain electrode in the case of the MOSFET, or a cathode electrode in the case of the diode, is provided.

In the semiconductor device 10 of Example 1, in a thermal equilibrium state, a depletion layer 3 spreading into the first semiconductor region 1 is continuous from the active region 11 to each of the second semiconductor regions 2, and each of the second semiconductor regions 2 is a substantially intrinsic region. One of the characteristics is that depletion (shrinkage of the intrinsic region) of each of the second semiconductor regions 2 due to application of a voltage begins from the second semiconductor region 2 on an outer periphery side (a side far from the active region 11).

Out of the second semiconductor regions 2 in the termination region 12, a plurality of second semiconductor regions 2 on a side closer to the active region 11 overlap each other to form one well region, which is also continuous with the second semiconductor region 2a in the active region 11. Out of the second semiconductor regions 2 in the termination region 12, the second semiconductor regions 2 on a side far from the active region 11 form well regions separated from each other.

Here, out of the second semiconductor regions 2 at which the depletion layer 3 spreading into the first semiconductor region 1 is continuous with the active region 11 in a thermal equilibrium state, the second semiconductor region 2 formed at a position farthest from the active region 11 will be referred to as the most outer peripheral second semiconductor region 2b at which the depletion layer 3 is continuous.

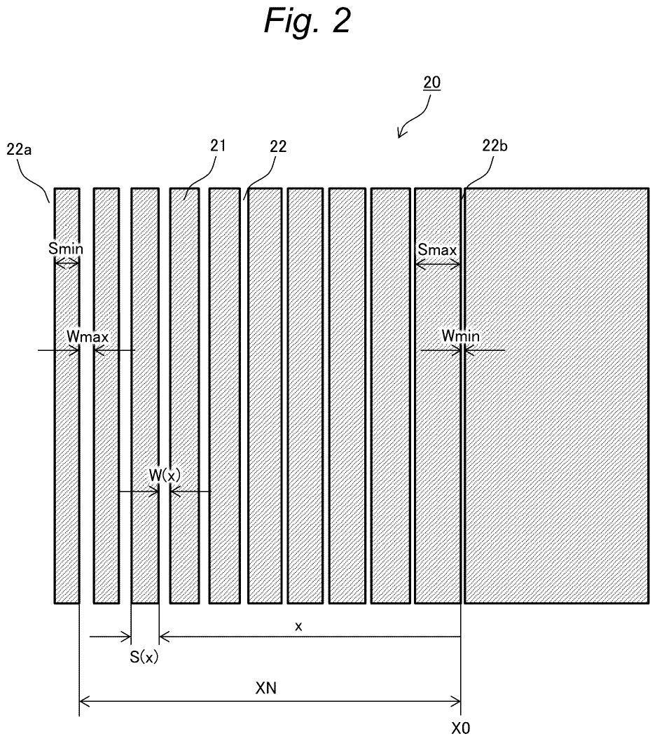

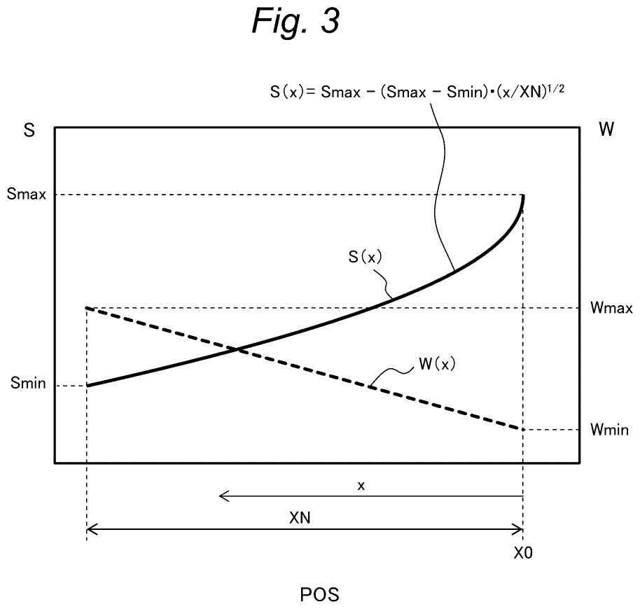

FIG. 2 is a plan view illustrating a shape of a mask of Example 1. FIG. 3 is a diagram illustrating a spacing between an injection window and the next injection window on a side of an active region in the mask of Example 1, and a width of the injection window.

In FIG. 3, a horizontal axis indicates a position POS, a vertical axis on the left indicates a spacing S (corresponding to a width of a blocking portion 21) between an injection window 22 of a mask 20 and the next injection window 22 on a side of the active region 11, and a vertical axis on the right indicates a width W of the injection window 22.

Impurities of a second conductivity type are injected using the mask 20 shown in FIG. 2 to form the second semiconductor regions 2. The mask 20 has the blocking portion 21 for blocking the impurities, and the injection window 22 which is an opening for allowing the impurities to pass through. Due to diffusion of the injected impurities, the size of the second semiconductor region 2 becomes larger than the size of the injection window 22.

Here, out of the injection windows 22, the injection window 22 corresponding to the second semiconductor region 2a of the active region 11 will be referred to as an active region injection window 22a, and the injection window 22 corresponding to the most outer peripheral second semiconductor region 2b at which the depletion layer 3 is continuous will be referred to as a reference window 22b.

The shape of the mask 20 in Example 1 is such that a spacing S(x) between the injection window 22 at a position of a distance x and the next injection window 22 on a side of the active region 11 is substantially equal to a value specified by the following equation (1), where a position of the reference window 22b on a side of the active region 11 is defined as X0, a distance between a position of the injection window 22 adjacent to the active region 11 on a side of the active region 11 and X0 is defined as XN, a spacing between the reference window 22b and the next injection window 22 on a side of the active region 11 is defined as Smax, a spacing between an end portion of the active region 11 and the injection window 22 adjacent to the active region 11 is defined as Smin, and a distance from X0 is defined as x.

$$S ( x ) = Smax - ( Smax - Smin ) \cdot {( x / XN )}^{1 / 2} \qquad ( 1 )$$

As a result, it is possible to realize reduction of the width of the termination region in the termination region 12 and suppression of electric field concentration in the termination region. Details of the effects will be described below.

In addition, the shape of the mask 20 in Example 1 is such that a width W(x) of the injection window 22 at a position of the distance x decreases with the distance increasing from the active region 11.

In this case, the width of the second semiconductor region 2 can be made smaller than in a case in which the width W(x) of the injection window 22 is constant regardless of the position of the distance x, and therefore the width of the termination region 12 can be reduced.

In Example 1, as shown in FIG. 3, the width W(x) of the injection window at the position of the distance x is made to decrease linearly with the distance increasing from the active region 11.

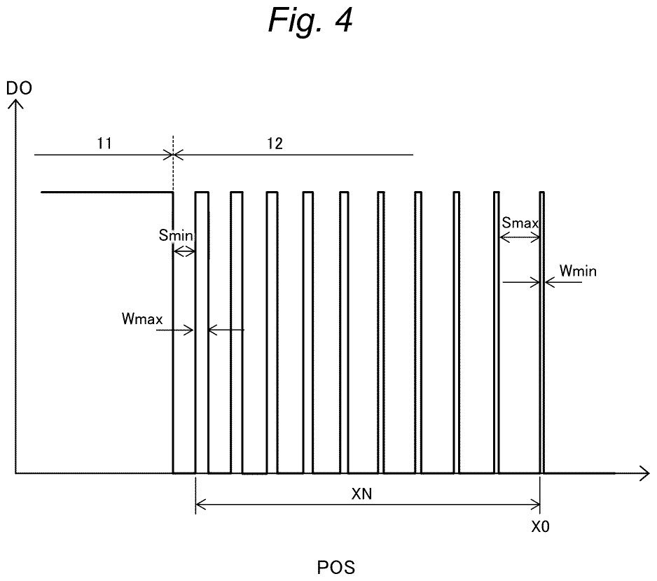

FIG. 4 is a diagram illustrating a dose profile of Example 1. In FIG. 4, a horizontal axis indicates a position POS, and a vertical axis indicates a dose amount DO.

In Example 1, when the impurities of the second conductivity type are injected using the mask 20, the dose profile is such that a dose amount in the second semiconductor region 2a of the active region 11 is substantially equal to a dose amount in the second semiconductor region 2 of the termination region 12.

As a result, it is possible to form the second semiconductor region 2 by injecting the impurities of the second conductivity type using a single mask 20.

Next, the effect of realizing the reduction of the width of the termination region 12 and the suppression of the electric field concentration in the termination region 12 due to the shape of the mask 20 of Example 1 will be described in detail.

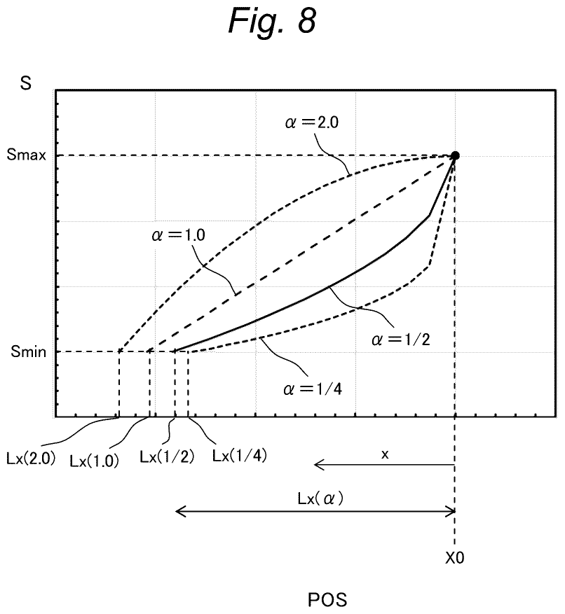

FIG. 8 is a diagram illustrating the effect of the present invention. In FIG. 8, a horizontal axis indicates a position POS, and a vertical axis indicates a spacing S (corresponding to a width of the blocking portion 21) between the injection window 22 of the mask 20 and the next injection window 22 on a side of the active region 11.

It is assumed that the spacing S(x) between the injection window 22 at the position of the distance x from X0 and the next injection window 22 on a side of the active region 11 can be expressed by the following equation (2)

$$S ( x ) = Smax - ( Smax - Smin ) \cdot {( x / Lx )}^{α} \qquad ( 2 )$$

In the case of α=½, this equation becomes the same as equation (1). Here, assuming that the number of injection windows 22 is 15 and the distance between the position of the injection window 22 adjacent to the active region 11 on a side of the active region 11 and X0 is Lx(x), the spacing S(x) and Lx(¼), Lx(½), Lx(1.0), and Lx(2.0) are calculated for α=¼, ½, 1.0, and 2.0, respectively, and are shown in FIG. 8.

As a result, it is found that the smaller x is, the smaller Lx(x) is, that is, the width of the termination region 12 can be made smaller.

Here, α=1.0 corresponds to the spacing S(x) increasing linearly toward the outer periphery of the termination region 12 (as x approaches 0), which is not strictly the same as, but roughly corresponds to the case in Patent Literature 1 in which the aperture ratio of the injection mask (20) decreases according to a linear function toward the outside of the termination structure (32). In addition, α=2.0 roughly corresponds to the case in Patent Literature 1 in which the aperture ratio of the injection mask (20) decreases according to the polynomial toward the outside of the termination structure (32). However, in the case of α=1.0 or α=2.0, Lx(1.0) or Lx(2.0) becomes larger than Lx(½), and it is found that this case is not suitable for reducing the width of the termination region 12.

In addition, although not shown in FIG. 8, calculations are also performed for a case in which the spacing S(x) changes depending on ex as an example of an exponential function (roughly corresponding to the case in which the aperture ratio of the injection mask (20) decreases according to an exponential function toward the outside of the termination structure (32) in Patent Literature 1), and the results are roughly close to the case of α=2.0. Therefore, it is found that this case is also not suitable for reducing the width of the termination region 12.

When a withstanding voltage is examined, it is about 900 V for all of α=¼, ½, 1.0, and 2.0, which is a sufficient withstanding voltage for use as a device with a withstanding voltage of 750 V.

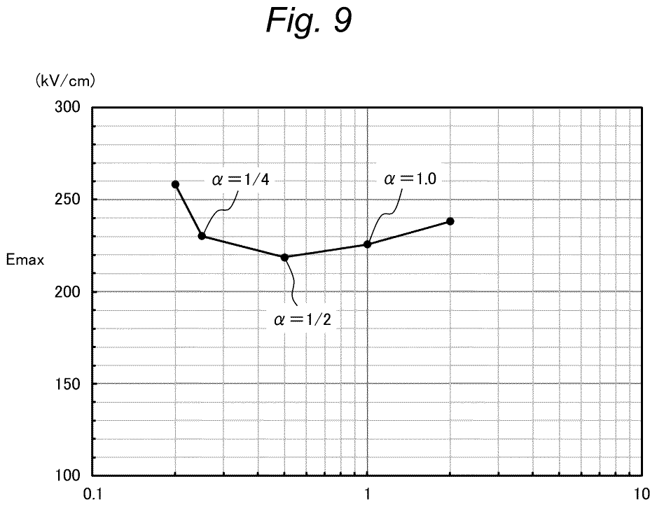

FIG. 9 is a diagram illustrating the effect of the present invention. In FIG. 9, a horizontal axis indicates, and a vertical axis indicates the maximum electric field strength Emax (kV/cm) in the termination region 12 when 750 V is applied.

As shown in FIG. 9, it is found that, in the case of α=½, the maximum electric field strength Emax is the smallest. The fact that the maximum electric field strength Emax is small means that the electric field concentration in the termination region 12 can be suppressed.

Avalanche breakdown is a phenomenon that occurs when electrons accelerated by an electric field collide with an atom, causing the electrons to be pulled away from the atom in an avalanche-like manner. When the electric field strength at which the breakdown occurs is Ec and the electric field strength is E, a current I increases suddenly in the form of the following equation (3).

$$I = {I}_{0} / [ 1 - {( E / Ec )}^{k} ] \qquad ( 3 )$$

Where I₀ and k are constants. In addition, since the avalanche breakdown occurs when the electric field strength E reaches the electric field strength Ec at which the breakdown occurs, E<Ec.

From equation (3), it can be seen that the smaller the electric field strength E is, the larger the denominator of equation (3) becomes and the smaller the current I becomes. As a result, the avalanche breakdown is less likely to occur and the smaller current is advantageous for ensuring long-term reliability when a voltage is applied for a long period of time. As shown in FIG. 9, it is found that, in the case of α=½, the maximum electric field strength Emax is the smallest, and therefore the electric field strength E and the current I become also small, which is most suitable.

It is found from FIG. 8 and FIG. 9 that the case of α=½ in equation (2), that is, equation (1), is most suitable.

As described above, according to Example 1, by using the mask 20 having a shape in which the spacing S(x) between the injection window 22 at the position of the distance x and the next injection window 22 on a side of the active region 11 is substantially equal to the value specified by equation (1), it is possible to realize reduction of the width of the termination region 12 and suppression of electric field concentration in the termination region 12.

### Example 2

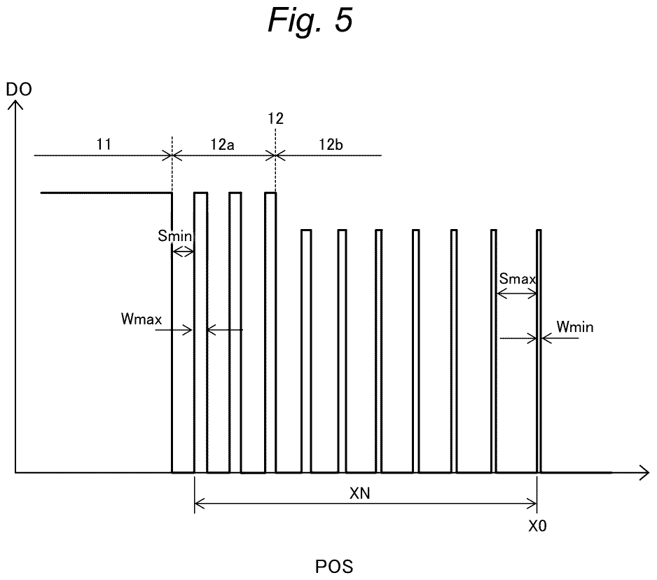

FIG. 5 is a diagram illustrating a dose profile of Example 2. FIG. 5 is a diagram corresponding to FIG. 4 of Example 1.

Example 2 differs from Example 1 in the dose profile.

The dose profile of Example 2 is, as shown in FIG. 5, a dose profile in which the dose amount of the second semiconductor region 2 in the termination region 12a on a side closer to the active region 11 in the termination region 12 is greater than the dose amount of the second semiconductor region 2 in the termination region 12b on a side farther from the active region 11 in the termination region 12.

As a result, there is the effect of suppressing a decrease in the withstanding voltage due to positive interface charges.

However, in Example 2, in order to change the dose amount depending on the region, it is necessary to inject the impurities of a second conductivity type using two masks 20, and thus Example 2 also differs from Example 1 in this point.

Other than the above, this example is the same as Example 1, and thus the overlapping description will be omitted.

### Example 3

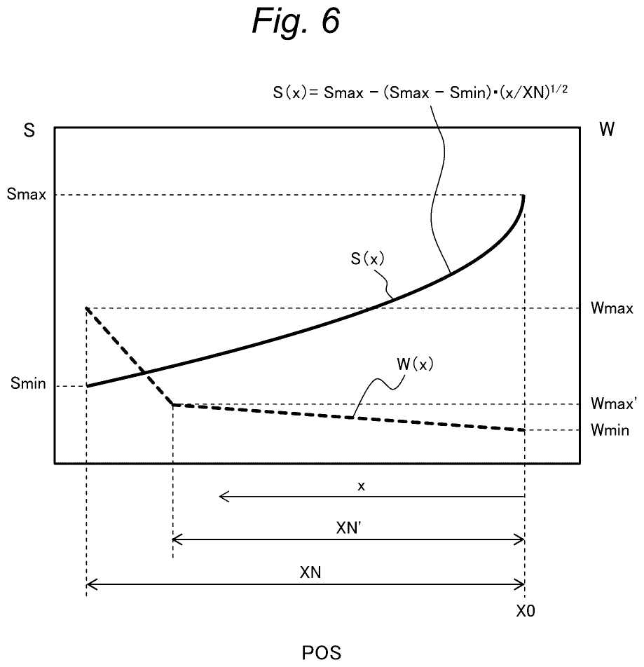

FIG. 6 is a diagram illustrating a spacing between an injection window and the next injection window on a side of an active region in a mask of Example 3, and a width of the injection window. FIG. 6 is a diagram corresponding to FIG. 3 of Example 1.

Example 3 differs from Example 1 in the width W(x) of the injection window 22 at the position of the distance x.

The shape of the mask 20 in Example 3 is such that a width W(x) of the injection window 22 at a position of the distance x decreases linearly with the distance increasing from the active region 11, and an inclination of a decrease on a side closer to the active region 11 (x>XN′) is greater than an inclination of a decrease on a side farther from the active region 11 (x≤XN′). In FIG. 6, Wmax′ is a value of the width W(x) of the injection window 22 at a position where the distance x is XN′.

Next, the reason for changing the inclination of the decrease in the width W(x) of the injection window 22 will be explained. Through heat treatment after injecting the impurities of the second conductivity type, the width of the second semiconductor region 2 is increased and the peak concentration is also decreased. The amount of decrease in the peak concentration is increased as the width W(x) of the injection window 22 is smaller, and is decreased as the width W(x) is larger. In contrast, the width of the injection window 22 in the second semiconductor region 2a in the active region 11 is extremely larger than the width W(x) of the injection window in the termination region 12, and thus the decrease in the peak concentration in the second semiconductor region 2a in the active region 11 is less than that in the case of the second semiconductor region 2 in the termination region 12. Therefore, a difference occurs in the peak concentration between the active region 11 and the second semiconductor region 2 adjacent thereto. Here, in a case in which there is a large difference in the concentration, there is a concern that electric field concentration may occur at the end of the active region 11, leading to a decrease in the withstanding voltage. For this reason, it is preferable that the width W(x) of the injection window 22 be larger in the vicinity of the active region 11. On the other hand, if the width W(x) of the injection window 22 is large, the overall width of the termination region 12 will become large, and thus it is preferable that the width W(x) be as small as possible. Since the countermeasure against the electric field concentration at the end of active region 11 is sufficient only in the vicinity of active region 11, as shown in FIG. 6, by making the shape of the mask such that the inclination of the decrease on a side closer to the active region 11 (x>XN′) is greater than the inclination of the decrease on a side farther from the active region 11 (x≤XN′), it is possible to reduce the overall width of the termination region 12 compared to the case of FIG. 3 while taking the countermeasure against the electric field concentration at the end of the active region 11. This is the reason why the inclination of the decrease in the width W(x) of the injection window 22 is changed.

In addition, as a result, even in a case in which the impurities of the second conductivity type are injected using the single mask 20 with the same dose profile as that shown in FIG. 4 of Example 1 to form the second semiconductor region 2, there is also the effect of suppressing a decrease in the withstanding voltage due to positive interface charges, as in the case of Example 2.

Other than the above, this example is the same as Example 1, and thus the overlapping description will be omitted.

### Example 4

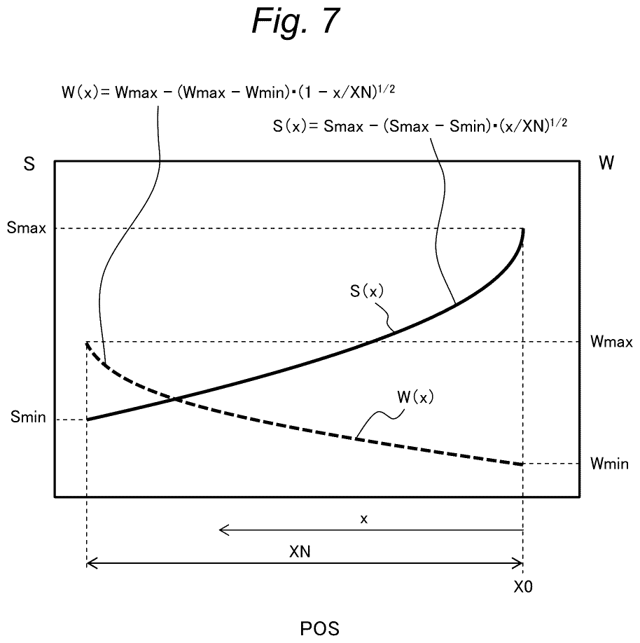

FIG. 7 is a diagram illustrating a spacing between an injection window and the next injection window on a side of an active region in a mask of Example 4, and a width of the injection window. FIG. 7 is a diagram corresponding to FIG. 3 of Example 1.

Example 4 differs from Example 1 and Example 3 in the width W(x) of the injection window 22 at the position of the distance x.

The shape of the mask 20 in Example 4 is such that a width W(x) of the injection window 22 at a position of the distance x is substantially equal to a value specified by the following equation (4), where a width of the injection window 22 at a position of a distance XN is defined as Wmax and a width of the injection window 22 as the reference window 22b is Wmin.

$$W ( x ) = Wmax - ( Wmax - Wmin ) \cdot {( 1 - x / XN )}^{1 / 2} \qquad ( 4 )$$

In Example 4, the width W(x) of the injection window 22 can be changed smoothly instead of linearly, and a decrease in the withstanding voltage due to positive interface charges can be suppressed.

Other than the above, this example is the same as Example 1 and Example 3, and thus the overlapping description will be omitted.

Although the examples of the present invention have been described above, the present invention is not limited to the configurations described in the examples, and various modifications are possible within the scope of the technical concept of the present invention. In addition, some or all of the configurations described in each example may be combined and applied.

### REFERENCE SIGNS LIST

1 First semiconductor region
2 Second semiconductor region
3 Depletion layer
4 Oxide film
5 Electrode
6 Channel stopper
10 Semiconductor device
11 Active region
12, 12a, 12b Termination region
20 Mask
21 Blocking portion
22 Injection window
22a Active region injection window
22b Reference window
S Spacing between injection window and next injection window on side of
active region
W Width of injection window
X Distance
DO Dose amount
POS Position

1. A method for manufacturing a semiconductor device that includes, in a periphery of an active region, a termination region in which second semiconductor regions, which are a plurality of well regions having a second conductivity type, are formed in a front surface of a first semiconductor region having a first conductivity type,
wherein the second semiconductor regions are formed by injecting impurities of the second conductivity type using, as a mask for forming the second semiconductor regions, a mask in which a spacing S(x) between an injection window at a position of a distance x and the next injection window on a side of the active region is substantially equal to a value specified by S(x)=Smax−(Smax−Smin)·(x/XN)^{1/2},
where, out of the second semiconductor regions at which a depletion layer spreading into the first semiconductor region is continuous with the active region in a thermal equilibrium state, the injection window corresponding to the second semiconductor region formed at a position farthest from the active region is defined as a reference window, a position of the reference window on a side of the active region is defined as X0, a distance between a position of the injection window adjacent to the active region on a side of the active region and X0 is defined as XN, a spacing between the reference window and the next injection window on a side of the active region is defined as Smax, a spacing between an end portion of the active region and the injection window adjacent to the active region is defined as Smin, and a distance from X0 is defined as x.

2. The method according to claim 1, wherein, in the mask, a width W(x) of the injection window at a position of the distance x decreases with the distance increasing from the active region.

3. The method according to claim 2, wherein, in the mask, a width W(x) of the injection window at a position of the distance x decreases linearly with the distance increasing from the active region.

4. The method according to claim 2, wherein, in the mask, a width W(x) of the injection window at a position of the distance x decreases linearly with the distance increasing from the active region, and an inclination of a decrease on a side closer to the active region is greater than an inclination of a decrease on a side farther from the active region.

5. The method according to claim 2, wherein, in the mask, a width W(x) of the injection window at a position of the distance x is substantially equal to a value specified by W(x)=Wmax−(Wmax−Wmin)·(1−x/XN)^{1/2},
where a width of the injection window at a position of the distance XN is defined as Wmax and a width of the injection window as the reference window is defined as Wmin.

6. The method according to claim 1, wherein, when the impurities of the second conductivity type are injected using the mask, a dose amount in the second semiconductor region of the active region is substantially equal to a dose amount in the second semiconductor region of the termination region.

7. The method according to claim 1, wherein, when the impurities of the second conductivity type are injected using the mask, a dose amount in the second semiconductor region on a side closer to the active region in the termination region is greater than a dose amount in the second semiconductor region on a side farther from the active region in the termination region.

8. A semiconductor device comprising an active region and a termination region formed in a periphery of the active region,
wherein the second semiconductor region formed using the method according to claim 1 is included in the termination region.

9. The semiconductor device according to claim 8, wherein, out of the second semiconductor regions, in a region from the second semiconductor region formed by the injection window adjacent to the active region to the second semiconductor region formed by the reference window, in a thermal equilibrium state, the depletion layer spreading into the first semiconductor region is continuous from the active region, each second semiconductor region is a substantially intrinsic region, and depletion of each of the second semiconductor regions occurring due to application of a voltage begins from the second semiconductor region formed by the reference window.

10. The semiconductor device according to claim 8, wherein, out of the second semiconductor regions, in a region from the second semiconductor region formed by the injection window adjacent to the active region to the second semiconductor region formed by the reference window, a plurality of the second semiconductor regions overlap each other on a side closer to the active region to form one well region, and the second semiconductor regions form the well regions separated from each other on a side farther from the active region.
